(19) United States
(12) Patent Application Publication
(10) Pub. No.: US 2005/0124127 A1
(43) Pub. Date: Jun. 9, 2005

(54) Method for manufacturing gate structure for use in semiconductor device

(76) Inventors: Tzu-En Ho, Jiaosi Township (TW); Chang-Rong Wu, Banciao City (TW); Yi-Nan Chen, Taipei City (TW); Kuo-Chien Wu, Miaoli City (TW)

Correspondence Address: Michael D. Bednarek;Shaw Pittman LLP, 1650 Tysons Boulevard, McLean, VA, 22102, US

(21) Appl. No.: 10/726,500

(22) Filed: Dec. 4, 2003

(51) Int. Cl. H01L 21/00; H01L 21/4763; H01L 21/336

(52) U.S. Cl. 438/303; 438/585; 438/592

(57) ABSTRACT

The present invention provides a method for manufacturing a stacked gate structure in a semiconductor device. The method includes the steps of sequentially forming a gate dielectric layer, a poly-silicon layer, a metal layer, a barrier layer, and a tungsten layer on a semiconductor substrate, carrying out a rapid thermal annealing (RTA) in a nitrogen ambient, forming a silicon nitride layer on the tungsten layer, and patterning the multilayer thin-film structure into a predetermined configuration.

### BACKGROUND OF THE INVENTION

1. Field of the Invention

The present invention generally relates to a method for manufacturing a stacked gate structure in a semiconductor device. More particular, the present invention relates to a method for manufacturing a stacked gate structure in a field effect transistor.

2. Description of Related Arts

Chip manufacturers have always tried to achieve higher device operating speed. Reduction of sheet resistance and contact resistance of a gate electrode is an effective way to accomplish the aforementioned goal. Therefore, a poly-Si/WN/W gate is now regarded as a potential structure in DRAM technology beyond 0.18 μm generation. The WN layer is used as a barrier layer to prevent inter-diffusion between the silicon atoms in the poly-silicon layer and the tungsten atoms in the WN/W layers. The sheet resistance of such gate structure is lower than 10 Ω/□, which is better than that of the conventional poly-Si/WSi structure.

FIGS. 1A and 1B are cross sectional views setting forth a conventional method for manufacturing a poly-Si/WN/W gate structure. To begin, a gate dielectric layer 102, a poly-silicon layer 104, a barrier layer 106, a tungsten (W) layer 108, and a silicon nitride layer 110 are sequentially formed on a semiconductor substrate 100, as shown in FIG. 1A. Thereafter, a lithography process and an etching process are performed and then the silicon nitride layer 110 is patterned to form a predetermined configuration, thereby obtaining a hard mask pattern 110A. Subsequently, the tungsten layer 108, the barrier layer 106, the poly-silicon layer 104 and the gate dielectric layer 102 are patterned to form the predetermined configuration, thereby obtaining a gate structure provided with a patterned gate dielectric layer 102A, a patterned poly-silicon layer 104A, a patterned barrier layer 106A and a patterned tungsten layer 108A, as shown in FIG 1B.

Conventionally, the method used to form a barrier layer 106 is to form a WNₓ layer or TiN layer on the poly-silicon layer. The barrier layer is used to prevent inter-diffusion between the silicon atoms in the poly-silicon layer and the tungsten atoms in the tungsten layer.

### SUMMARY OF THE INVENTION

It is an objective of the present invention to provide a method for manufacturing a stacked gate structure in a semiconductor device. The gate structure manufactured using such method is provided with lower gate sheet resistance and contact resistance.

To attain the objective, the present invention provides a method for manufacturing a stacked gate structure. The method comprises the steps of: 1) sequentially forming a gate dielectric layer, a poly-silicon layer, a metal layer, a barrier layer, and a tungsten layer on a semiconductor substrate; 2) performing a rapid thermal annealing process in a nitrogen ambient; thereby forming a silicide layer as a result of the reaction between the metal layer and the poly-silicon layer; 3) patterning the tungsten layer, the barrier layer, the silicide layer and the poly-silicon layer to form a stacked gate structure.

In addition, the present invention provides another method for manufacturing a stacked gate structure, the method comprising the steps of: 1) sequentially forming a gate dielectric layer, a poly-silicon layer, a metal layer, a barrier layer, and a tungsten layer on a semiconductor substrate; 2) patterning the tungsten layer, the barrier layer, the metal layer and the poly-silicon layer to form a stacked gate structure. 3) performing a rapid thermal annealing process in a nitrogen ambient; thereby forming a silicide layer as a result of the reaction between the metal layer and the poly-silicon layer.

Moreover, the present invention provides a method for manufacturing a field effect transistor, the method comprising the steps of 1) forming the stacked gate structure consisting of a poly-silicon layer, a silicide layer, a barrier layer and a tungsten layer using the aforementioned method; 2) performing an ion implantation process, using the stacked gate electrode as a mask, to form spaced apart first source/drain regions in the semiconductor substrate; 3) forming a sidewall spacer adjacent to the stacked gate structure; 4) performing another ion implantation process, using the sidewall spacer as a mask, to form spaced apart second source/drain regions of higher doping concentration than the first source/drain regions.

### BRIEF DESCRIPTION OF THE DRAWINGS

FIGS. 1A and 1B are cross sectional views setting forth for a conventional method for manufacturing a poly-S/WN/W gate structure

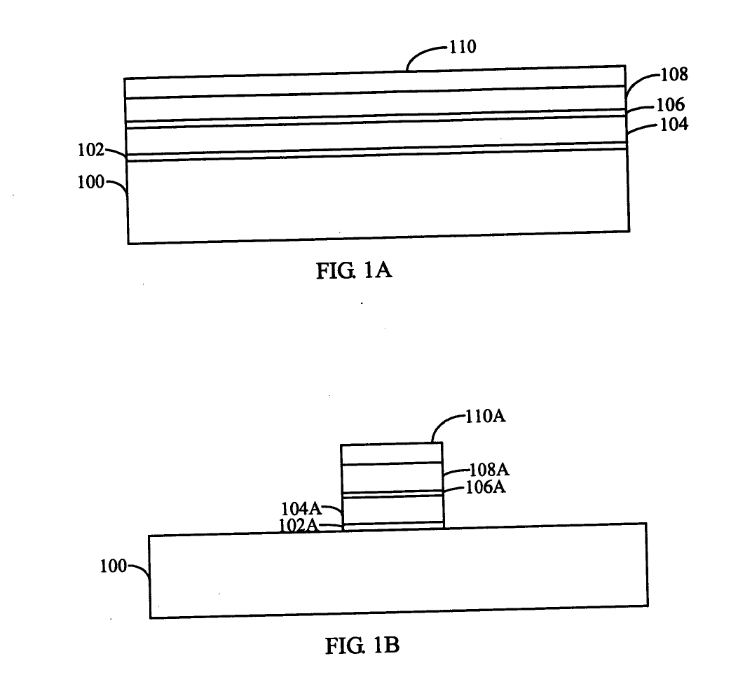

FIGS. 2A to 2C are cross sectional views setting forth a method for manufacturing a stacked gate structure in accordance with one preferred embodiment of the present invention.

FIGS. 3A to 3C are cross sectional views setting forth a method for manufacturing a stacked gate structure in accordance with another preferred embodiment of the present invention.

FIGS. 4 is a cross sectional view setting forth a method for manufacturing a field effect transistor provided with a stacked gate structure in accordance with one preferred embodiment of the present invention.

### DETAILED DESCRIPTION OF THE PREFERRED EMBODIMENTS

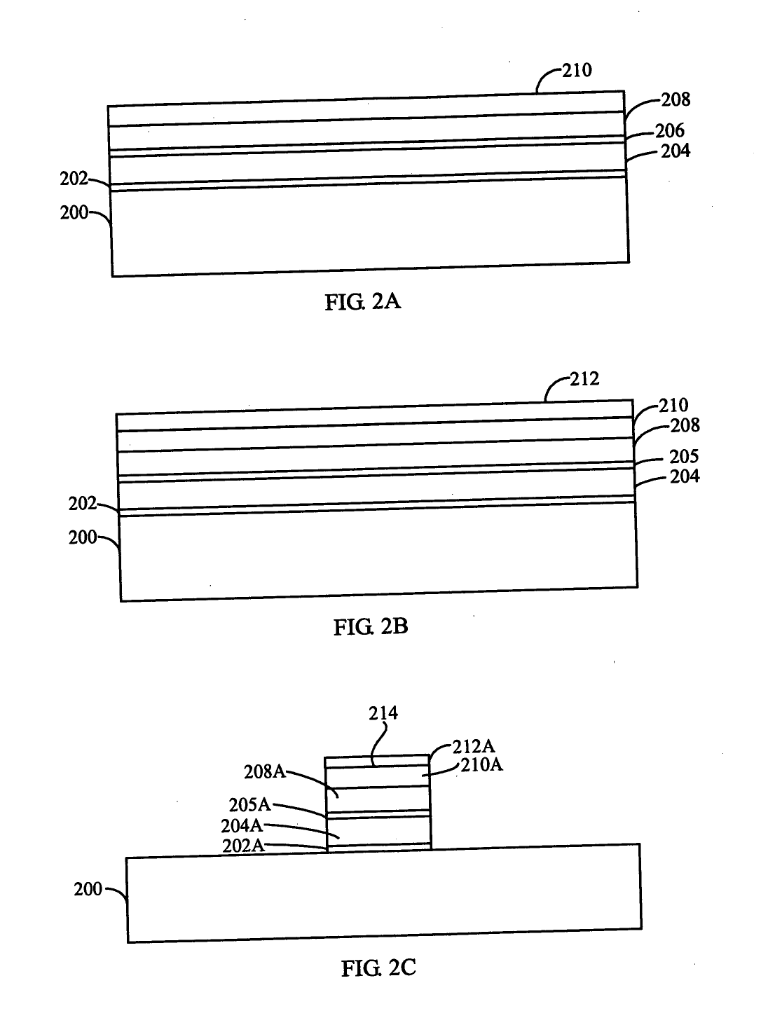

Referring to FIG. 2A˜2C, FIGS. 2A to 2C are cross sectional views setting forth a method for manufacturing a stacked gate structure in accordance with one preferred embodiment of the present invention. To begin, a gate dielectric layer 202, a poly-silicon layer 204, a metal layer 206, a barrier layer 208, and a tungsten layer 210 are formed on a semiconductor substrate 200, as shown in FIG. 2A. The gate dielectric layer 202 can be made of SiO2, SiNₓ, Si₃N₄, SiON, TaO₂ or TaON. The thickness of the poly-silicon layer 204 is about 500˜2000 angstroms and can be formed by chemical vapor deposition(CVD). The metal layer 206 can be made of titanium(Ti), cobalt(Co), nickel(Ni), platinum(Pt), tungsten(W), tantalum(Ta), molybdenum(Mo), hafnium(Hf) or niobium(Nb). The thickness of the metal layer 206 is about 5˜30 angstroms and the metal layer 206 can be formed by chemical vapor deposition or physical vapor deposition. The barrier layer can be made of WN, TaN, or TiN. The thickness of the barrier layer 208 is about 50˜100 angstroms and the barrier layer 208 can be formed by physical vapor deposition or sputtering. Thereafter, a rapid thermal annealing process is performed in a nitrogen ambient at 750˜1150° C. for 60˜120 seconds. During the process of the rapid thermal annealing, a silicide layer 205 is formed, as shown in FIG. 2B, as a result of the chemical reaction between the metal layer 206 and the poly-silicon layer 204. The formation of the silicide layer 205 can reduce the sheet resistance of the gate electrode and prevent the formation of SiN, whose resistance is rather high, as a result of the reaction between the nitrogen atoms in the barrier layer 208 and the silicon atoms in the poly-silicon layer 204. Subsequently, a silicon nitride layer 212 is deposited on the tungsten layer 210. The silicon nitride layer 212 has a thickness of about 500˜3000 angstroms and can be formed by growth in the furnace or chemical vapor deposition in the chamber. At last, as shown in FIG. 2C, a photolithography process and an etching process are performed. Thereby, the silicon nitride layer 212 is patterned to form a hard mask 212A consistent with the predetermined configuration on the photo mask. Next, an etching process is performed to obtain a stacked gate structure 214 provided with a patterned poly-silicon layer 204A, a patterned silicide layer 205A, a patterned diffusion barrier layer 208A and a patterned tungsten layer 210A.

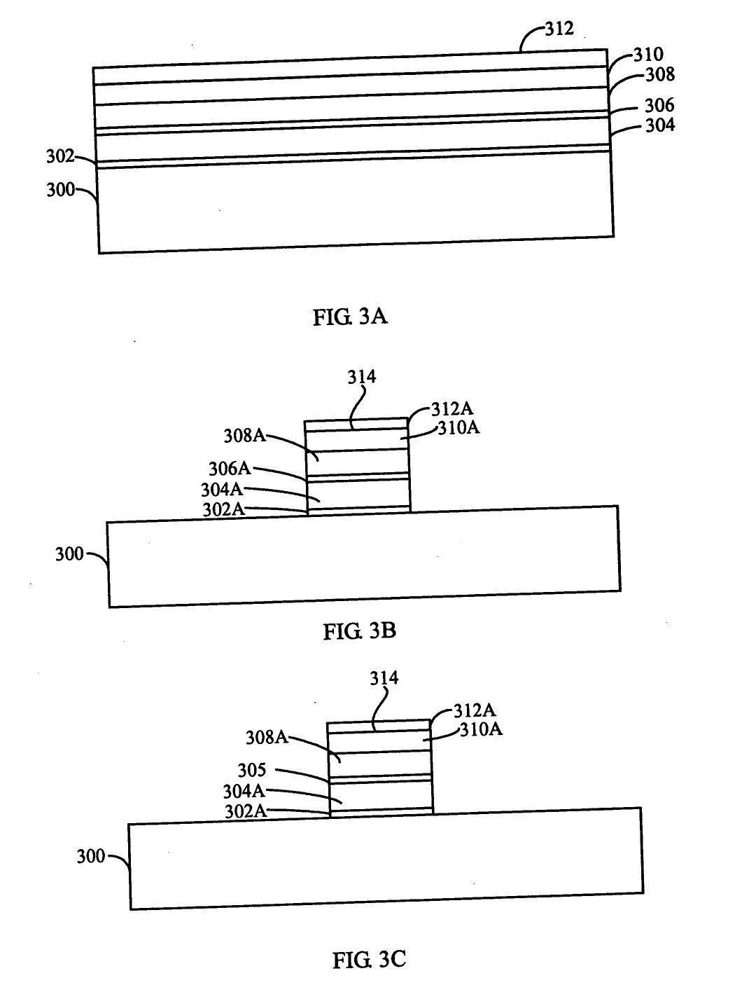

In addition, the present invention also provides another method for manufacturing a stacked gate structure, the method comprising the steps of sequentially forming a gate dielectric layer 302, a poly-silicon layer 304, a metal layer 306, a barrier layer 308, a tungsten layer 310 and a silicon nitride layer 312 on a semiconductor substrate 300, as shown in FIG. 3A. The gate dielectric layer 302 may be made of SiO2, SiNₓ, Si₃N₄, SiON, TaO₂ or TaON. The thickness of the poly-silicon layer 304 is about 500˜2000 angstroms and can be formed by chemical vapor deposition(CVD). The metal layer 306 maybe made of titanium(Ti), cobalt(Co), nickel(Ni), platinum(Pt), tungsten(W), tantalum(Ta), molybdenum(Mo), hafnium(Hf) or niobium(Nb). The thickness of the metal layer 306 is about 5˜30 angstroms and can be formed by chemical vapor deposition or physical vapor deposition. The barrier layer 308 can be made of WN, TaN, or TiN. The thickness of the barrier layer 308 is about 50˜100 angstroms and the barrier layer 308 can be formed by physical vapor deposition or sputtering. The thickness of the tungsten layer 310 is about 250˜800 angstroms and can be formed by physical vapor deposition or sputtering. The silicon nitride layer 312 has a thickness of about 500˜3000 angstroms and can be formed by growth in the furnace or chemical vapor deposition in the chamber. Thereafter, a lithography process and an etching process are performed. The silicon nitride layer 312 is patterned to form a hard mask consistent with the pre-determined configuration on the photo mask. Next, an etching process is performed to get a stacked gate structure 314 provided with a patterned dielectric layer 302A, a patterned poly-silicon layer 304A, a patterned metal layer 306A, a patterned barrier layer 308A, and a tungsten layer 310A. Besides, there is a hard mask, a patterned silicon nitride layer 312A, on the stacked gate structure, as shown in FIG. 3B. Finally, a rapid thermal annealing process is performed in a nitrogen ambient at 750˜1150° C. for 60˜120 seconds. During the process of the rapid thermal annealing, a silicide layer 305 is formed, as shown in FIG. 3C, as a result of the chemical reaction between the metal layer 308A and the poly-silicon layer 304A. The formation of the silicide layer 305 can reduce the sheet resistance of the gate electrode and prevent the formation of SiN, whose resistance is rather high as a result of the reaction between the nitrogen atoms in the barrier layer 308A and the silicon atoms in the poly-silicon layer 304A.

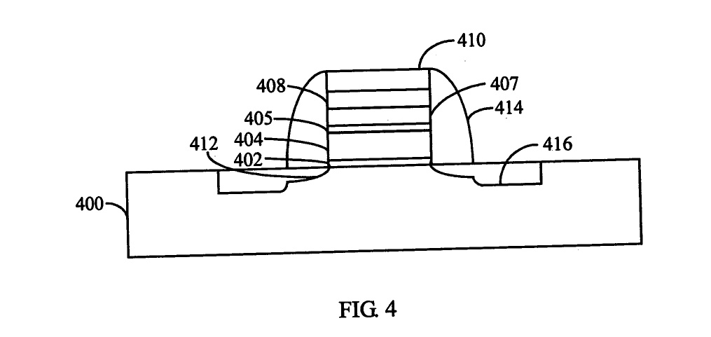

Besides, the present invention also provides a method for manufacturing a field effect transistor. The steps of the method starts with forming a stacked gate structure provided with a patterned dielectric layer 402, a patterned poly-silicon layer 404, a patterned layer 405, a patterned layer 407 and a patterned tungsten layer 408 on the semiconductor substrate 400 using one of the aforementioned methods. There is a hard mask, a patterned silicon nitride layer 410, on the stacked gate structure, as shown in FIG. 4. The ions are implanted into the semiconductor substrate 400 using the stacked gate structure as a mask, to form spaced apart first source/drain regions in the semiconductor substrate. A sidewall spacer 414 is formed on the sidewalls of the stacked gate structure. And then, ions are implanted into the semiconductor substrate 400 using the sidewall spacer as a mask, to form spaced apart second source/drain regions 416 of higher doping concentration than the first source/drain regions 412.

In accordance with the present invention, during the process of rapid thermal annealing, a silicide layer is formed as a result of the chemical reaction between the metal layer and the poly-silicon layer. The formation of the silicide layer can reduce the gate sheet resistance and prevent the formation of SiN, whose sheet resistance is rather high, as a result of the reaction between the nitrogen atoms in the barrier layer and the silicon atoms in the poly-silicon layer. Therefore, a higher device operating speed can be obtained.

Although the description above contains much specificity, it should not be construed as limiting the scope of the invention but as merely providing illustrations of some of the presently preferred embodiments of the present invention. Thus, the scope of the present invention should be determined by the appended claims and their equivalents, rather than by the examples given.

1. A method for manufacturing a stacked gate structure, the method comprising the steps of:
a) sequentially forming a dielectric layer, a poly-silicon layer, a metal layer, a barrier layer, and a tungsten layer on a semiconductor substrate;
b) performing a rapid thermal annealing (RTA) process and thereby forming a silicide layer as a result of the reaction between said metal layer and said poly-silicon layer; and
c) patterning said tungsten layer, said barrier layer and said silicide layer and said poly-silicon layer to form said stacked gate structure.

2. The manufacturing method as claimed in claim 1, wherein said metal layer is made of metal selected from a group consisting of titanium, cobalt, nickel, platinum, tungsten, tantalum, molybdenum, hafnium and niobium.

3. The manufacturing method as claimed in claim 1, wherein said barrier layer is made of metal nitride selected from a group consisting of WN, TaN, and TiN.

4. The manufacturing method as claimed in claim 1, wherein, said rapid thermal annealing process is performed in a nitrogen ambient.

5. A method for manufacturing a stacked gate structure, the method comprising the steps of:
a) sequentially forming a dielectric layer, a poly-silicon layer, a metal layer, a barrier layer, and a tungsten layer on a semiconductor substrate;
b) patterning said tungsten layer, said barrier layer, said metal layer, and said poly-silicon layer to form said stacked gate structure; and
c) performing a rapid thermal annealing (ETA) process and thereby forming a silicide layer as a result of the reaction between said metal layer and said poly-silicon layer.

6. The manufacturing method as claimed in claim 5, wherein said metal layer is made of metal selected from a group consisting of titanium, cobalt, nickel, platinum, tungsten, tantalum, molybdenum, hafnium and niobium.

7. The manufacturing method as claimed in claim 5, wherein said barrier layer is made of metal nitride selected from a group consisting of WN, TaN, and TiN.

8. The manufacturing method as claimed in claim 5, wherein said rapid thermal annealing process is performed in a nitrogen ambient.

9. A method for manufacturing a field effect transistor, the method comprising the steps of:
a) sequentially forming a dielectric layer, a poly-silicon layer, a metal layer and a barrier layer, and a tungsten layer on a semiconductor substrate;
b) performing a rapid thermal annealing (RTA) process and thereby forming a silicide layer as a result of the reaction between said metal layer and said poly-silicon layer;
c) patterning said tungsten layer, said barrier layer and said silicide layer and said poly-silicon layer to form said stacked gate structure;
d) performing an ion implantation process, using said stacked gate electrode as a mask, to form spaced apart first source/drain regions in said semiconductor substrate;
e) forming a sidewall spacer adjacent to said stacked gate structure; and
f) performing another ion implantation process, using said sidewall spacer as a mask, to form spaced apart second source/drain regions of higher doping concentration than said first source/drain regions.

10. The manufacturing method as claimed in claim 9, wherein said metal layer is made of metal selected from a group consisting of titanium, cobalt, nickel, platinum, tungsten, tantalum, molybdenum, hafnium and niobium.

11. The manufacturing method as claimed in claim 9, wherein said barrier layer is made of metal nitride selected from a group consisting of WN, TaN, and TiN.

12. The manufacturing method as claimed in claim 9, wherein said rapid thermal annealing process is performed in a nitrogen ambient.

13. A method for manufacturing a field effect transistor, the method comprising the steps of:
a) sequentially forming a dielectric layer, a poly-silicon layer, a metal layer, a barrier layer, and a tungsten layer;
b) patterning said tungsten layer, said barrier layer, said metal layer, and said poly-silicon layer into said stacked gate structure;
c) performing a rapid thermal annealing (RTA) process, thereby forming a silicide layer as a result of the reaction between said metal layer and said poly-silicon layer;
d) performing an ion implantation process, using said stacked gate electrode as a mask, to form spaced apart first source/drain regions in said semiconductor substrate;
e) forming a sidewall spacer adjacent to said stacked gate structure; and
f) performing another ion implantation process, using said sidewall spacer as a mask, to form spaced apart second source/drain regions of higher doping concentration than said first source/drain regions.

14. The manufacturing method as claimed in claim 13, wherein said metal layer is made of metal selected from a group consisting of titanium, cobalt, nickel, platinum, tungsten, tantalum, molybdenum, hafnium and niobium.

15. The manufacturing method as claimed in claim 13, wherein said barrier layer is made of metal nitride selected from a group consisting of WN, TaN, and TiN.

16. The manufacturing method as claimed in claim 13, wherein said rapid thermal annealing process is performed in a nitrogen ambient.
